(19) United States
(12) Patent Application Publication
(10) Pub. No.: US 2023/0089096 A1
(43) Pub. Date: Mar. 23, 2023

(54) MULTIPLE DIES COUPLED WITH A GLASS CORE SUBSTRATE

(71) Applicant: Intel Corporation, Santa Clara, CA (US)

(72) Inventors: Andrew COLLINS, Chandler, AZ (US); Srinivas V. PIETAMBARAM, Chandler, AZ (US); Sanka GANESAN, Chandler, AZ (US); Tarek A. IBRAHIM, Mesa, AZ (US); Russell MORTENSEN, Chandler, AZ (US)

(21) Appl. No.: 17/481,234

(22) Filed: Sep. 21, 2021

(51) Int. Cl. H01L 23/538; H01L 25/00; H01L 25/065; H01L 21/48

(52) U.S. Cl. CPC H01L 23/5384; H01L 21/486; H01L 23/5385; H01L 23/5389; H01L 25/50; H01L 25/0655; H01L 25/0652

(57) ABSTRACT

Embodiments described herein may be related to apparatuses, processes, and techniques directed to packages that include one or more dies that are coupled with one or more glass layers. These glass layers may be within an interposer or a patch to which the one or more dies are attached. In addition, these glass layers may be used to facilitate pitch translation between the one or more dies proximate to a first side of the glass layer and a substrate proximate to a second side of the glass layer opposite the first side, to which the one or more dies are electrically coupled. Other embodiments may be described and/or claimed.

### FIELD

Embodiments of the present disclosure generally relate to the field of semiconductor packaging, and in particular glass core interposers.

### BACKGROUND

Continued growth in computing and mobile devices will continue to increase the demand for semiconductor packages with decreased warpage characteristics.

### BRIEF DESCRIPTION OF THE DRAWINGS

FIG. 1 illustrates a diagram of a glass interposer and a legacy silicon interposer used in a package, in accordance with various embodiments.

FIG. 2 illustrates a block diagram of a package with a glass-core patch with an active die complex coupled with a first side of the patch and a silicon interposer attached to the second side of the patch, in accordance with various embodiments.

FIG. 3 illustrates a block diagram of a package with a glass core interposer with an active die complex coupled with the first side of the glass core interposer and a motherboard attached to the second side of the glass core interposer, in accordance with various embodiments.

FIG. 4 illustrates a block diagram of a package with an active die complex that are electrically coupled using an asymmetric glass substrate which is physically coupled to an organic substrate, in accordance with various embodiments.

FIG. 5 illustrates a block diagram of a package with two sets of active die complexes each coupled with a glass interposer which is attached to a substrate that includes a bridge embedded within the substrate, in accordance with various embodiments.

FIG. 6 illustrates a cross section side view and two top-down views of a stacked die package on a glass interposer substrate, in accordance with various embodiments.

FIGS. 7A-7G illustrates stages in the manufacturing process for creating a stacked die package on a glass substrate, in accordance with various embodiments.

FIG. 8 illustrates multiple examples of laser-assisted etching of glass interconnects processes, in accordance with various embodiments.

FIG. 9 illustrates an example of a process for coupling a substrate with a glass core with a plurality of dies control warpage in a package, in accordance with various embodiments.

FIG. 10 schematically illustrates a computing device, in accordance with various embodiments.

### DETAILED DESCRIPTION

Embodiments described herein may be related to apparatuses, processes, and techniques directed to packages that include one or more dies, such as an active die complex, that are coupled with one or more glass layers. These glass layers, which may be referred to as a glass core, may be within an interposer or a patch to which the one or more dies are attached. In addition, these glass layers may be used to facilitate pitch translation between the one or more dies proximate to a first side of the glass layer and a substrate proximate to a second side of the glass layer opposite the first side, to which the one or more dies are electrically coupled. In embodiments, this substrate may include but is not limited to a standard organic substrate, an organic interposer, or a high-density motherboard.

In embodiments, an interposer with a glass layer may serve as a carrier substrate for an active die complex, as well as serve as a base for patterning high density die-to-die wire connections as well as vertical pass-throughs, such as through glass vias (TGV), through the glass layer. These TGVs may be used for signal transmission as well as for access to off-package power sources.

Using glass layers enables fine pitch vertical connections using TGV through the glass core. In addition, due to the flatness of the glass layer, fine trace routings on or proximate to surfaces of the glass layer are possible. A thickness of the glass layer may be chosen for increased mechanical performance of the package, in particular to prevent warpage of the package during manufacturing, insertion, or operation. This is due to the rigidity of the glass layer, particularly in comparison to an organic core that may include a carbon clad laminate (CCL), which may result in a more uneven surface and may warp more easily under mechanical stress or thermal stress. Increased thickness of the glass layer may be chosen to increase the mechanical reliability and performance of the one or more die and interposer complex. In embodiments, using glass layers may result in a reduction of the size of a package, in particular because of rigid glass core enables a tighter pitch of electrical connections (TGVs) through the glass layer that electrically couples the one or more dies above the glass layers with the substrate below the glass layers.

One legacy implementation may include a patch-on-interposer architecture, where a die complex is mounted on one side of a high density organic package, which may be referred to as a patch, which fans a first level interconnect (FLI) bump pitch out to a middle level interconnect (MLI). In legacy implementations, the solder ball pitch may be at approximately 0.6 mm pitch. In implementations, the organic patch may be mounted on a low density organic interposer for further pitch translation to a land grid array (LGA) socket at approximately 1 mm pitch. This legacy architecture has limitations due to the top side fit of the die complex or pinout constraints of the MLI pitch. These limitations may be referred to as bottom side limitations. In embodiments related to such bottom limited form factors, a patch construction that includes a glass layer would provide improved mechanical performance and enable reduced MLI pitches to reduce the overall patch form factor.

Another legacy implementation may include a direct chip attach (DCA) architecture, in which one or more dies are mounted on a passive silicon based die which fans the FLI bump pitch out to a 200-300 µm MLI pitch for direct mounting on a high-density motherboard. This legacy architecture has a challenge with warpage control. For example, the base die thickness is driven by the through silicon via (TSV) reveal process, which forces a legacy base die thickness below 100 µm. Thus, it is a challenge to maintain a large, flat die complex with a fine MLI pitch to try to minimize the size of the base die using this legacy architecture.

Still another legacy implementation may include multiple dies mounted on a passive silicon base die. In implementations, this passive base die can provide top mount active die to die high density connectivity as well as providing a pass-through path for off die signaling and power delivery. This legacy implementation has a challenge where the size of the silicon -based die may be limited by silicon wafer reticle limitations. In legacy implementations, larger base dies are possible with expensive reticle stitching techniques, but they require careful planning and design. In addition, in these legacy implementations with die complexes that include bridges, the base die TSV reveal process may force a thin base die, which impacts the die complex co-planarity due to warpage. Additionally, package side bump (PSB) pitch may be larger than desired due to increase warpage risk, which may cause a larger die size.

In embodiments, glass core-based substrates may use via patterning processes described herein to enable fine pitch TGVs and electrical connections with a high glass core thickness in order to vary pitch aspect ratios. The thickness of the glass core may be readily increased to improve mechanical performance. As a result, the rigid glass core may provide tighter pitches and may result in overall glass interposer, glass patch, or overall package size reduction.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

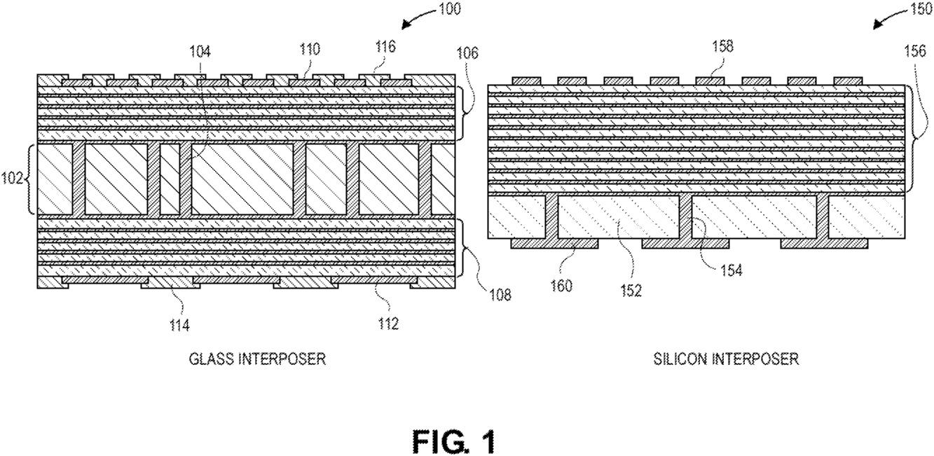

FIG. 1 illustrates a diagram of a glass interposer and a legacy silicon interposer used in a package, in accordance with various embodiments. Glass interposer 100 is an embodiment of a substrate that may be used to electrically and/or physically couple one or more dies (not shown) to a first side of the glass interposer 100 and a substrate (not shown) to the second side.

In embodiments, glass interposer 100 includes a glass core 102, and may have a first build up layer 106 on a first side of the glass core 102, and/or a second build up layer 108 on a second side of the glass core 102 opposite the first side. In embodiments, the glass core 102 may have multiple TGVs 104 that extend from the first side of the glass core 102 through the second side of the glass core 102, and may include copper or some other electrically conductive material to electrically couple the first side of the glass core 102 with the second side of the glass core 102.

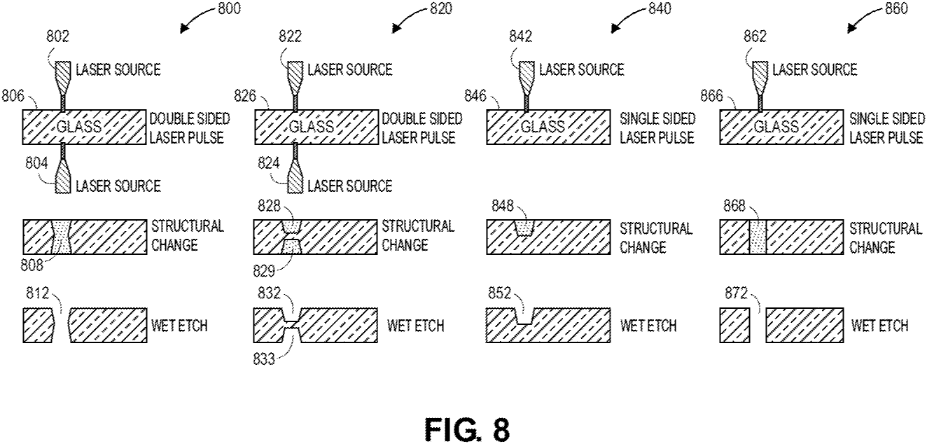

In embodiments, the first build up layer 106 and/or the second build up layer 108 may include multiple sublayers that may include metal routing layers interleaved with dielectric layers. In embodiments, the metal routing layers may be electrically coupled with each other and/or with the TGVs 104 to electrically couple one or more pads 110 on the first side, that may be separated by dielectric 116, with one or more substrate attach points 112 on the second side, that may be separated with dielectric 114. In embodiments, a thickness of the glass core 102 may be chosen based on a desired mechanical strength of the glass interposer 100. In addition, a pitch of the formed TGVs 104 may be very tight, as described below with respect to FIG. 8.

Legacy silicon interposer 150 includes a non-glass core 152, which may include a silicon core or an organic CCL core. There may be a build up layer 156 coupled with the side of the non-glass core 152. The non-glass core 152 may include a plurality of TSV 154. The legacy silicon interposer 150 may include a plurality of sublayers that includes metal routing layers interleaved with dielectric layers. In embodiments, the metal routing layers may be electrically coupled with each other and/or with the TSVs 154 to electrically couple one or more pads 158 with one or more substrate attach points 160.

With respect to glass interposer 100, the glass core 102 has a greater strength and flatness characteristics as compared to the organic (non-glass) core 152. As a result, the glass core 102 allows the metal routing layers within the first build up layer 106 and/or the second build up layer 108 to have a much finer pitch, and as a result the pads 110 may also be placed at a finer pitch, in comparison to the legacy silicon interposer 150.

Glass core-based substrates, such as glass interposer 100, also offer improved thermo-mechanical behavior. This includes lower warpage at both room temperature as well as temperatures elevated for solder attach processes during assembly, as well as elevated temperatures during product operation. As a result, in embodiments, glass core-based substrates may enable larger die-to-glass patch/interposer/package ratios at a fixed pitch or, in embodiments, can be used to reduce solder attach pitches. TGV 104 offers fine pitch through -core interconnects with more flexibility to increase the glass thickness while maintaining a high density signal pass-through through the glass core 102.

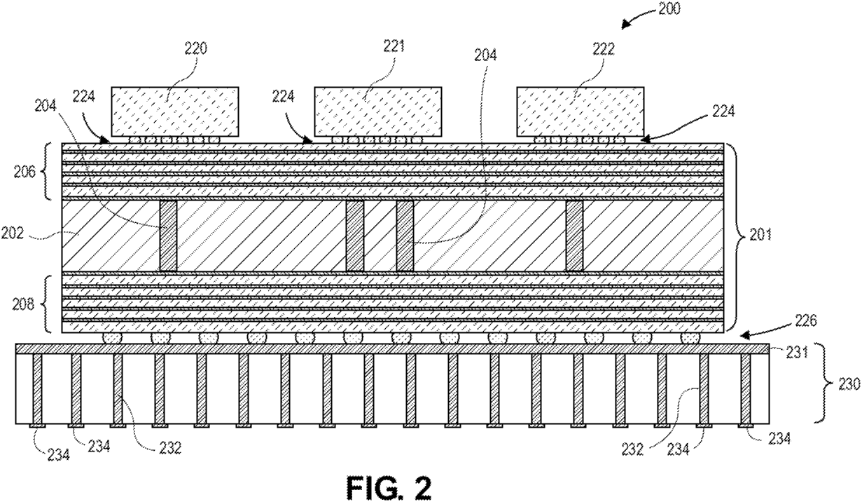

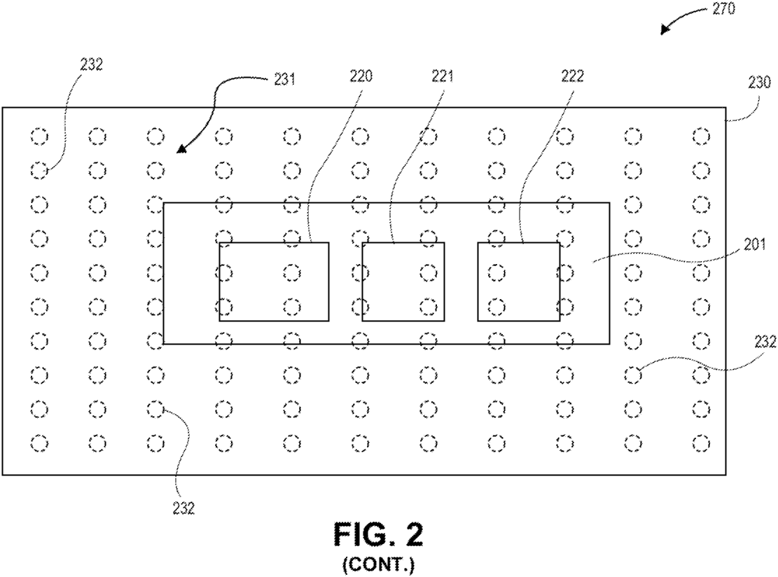

FIG. 2 illustrates a block diagram of a side view cross-section of a package with a glass-core patch with an active die complex coupled with a first side of the patch and a silicon interposer attached to the second side of the patch, in accordance with various embodiments. Package 200 includes a patch 201, that may be similar to substrate 100 of FIG. 1. Patch 201, which may also be referred to as a glass patch, includes a glass core 202 a first build up layer 206 and a second build up layer 208, that may be similar to glass core 102, first build up layer 106, and second build up layer 108 of FIG. 1.

A plurality of TGVs 204 may extend from a first side of the glass core 202 to a second side of the glass core 202 opposite the first side to electrically couple the first build up layer 206 and the second build up layer 208. In embodiments, a plurality of dies 220, 221, 222 may be electrically and/or physically coupled with a side of the first build up layer 206. In embodiments, the dies 220, 221, 222 may be coupled with the second build up layer 208 through a set of first level interconnects (FLI) 224.

A mid-level interconnect (MLI) 226 may electrically and physically couple the second build up layer 208 with an interposer 230. In embodiments, the interposer 230 may be either a silicon interposer or a glass interposer. In embodiments, the interposer 230 may be a fanout organic interposer. Package 270, which shows a top-down view of package 200, shows dies 220, 221, 222 physically and electrically coupled with the glass patch 201, which is in turn physically and electrically coupled with the routing layer 231 of interposer 230, which electrically couples a plurality of through vias 232 that are electrically coupled to a plurality of pads 234. This example embodiment shows a fanout example of the interposer 230.

In embodiments, the rigidity of the glass patch 201 provided by the glass core 202, by carefully choosing the coefficient of thermal expansion (CTE) and thickness of the glass improves the thermo-mechanical performance of the FLI 224 and the MLI 226. This may shrink FLI 224 pitch and increase the size of top dies. In addition, the flatness of the glass core 202 may be used to reduce the FLI 224 pitch, which would therefore enable smaller active dies 220, 221, 222 for implementations that otherwise would be bump pitch limited. In addition, in embodiments, the MLI 226 pitch may also be reduced to support smaller glass patch 201 form factors for implementations that otherwise would be limited by legacy MLI design. In embodiments, the finer pitch through core interconnect enables routing on the glass patch 201 similar to coreless substrates. This enables seamless transition between top and bottom side layers of the glass patch, which may enable more efficient patch routing schemes that may be used to reduce layer count.

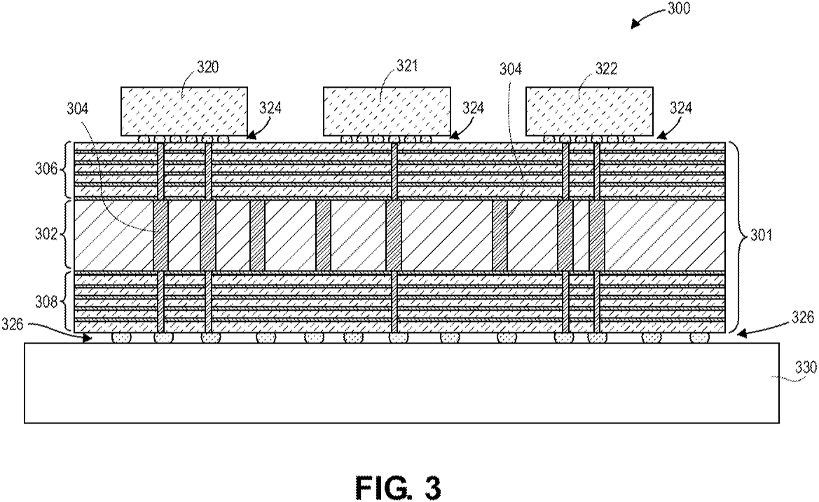

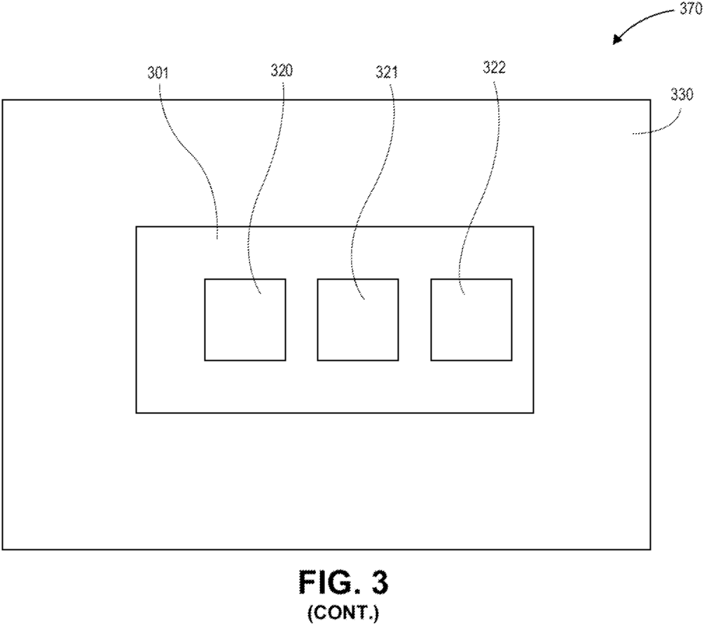

FIG. 3 illustrates a block diagram of a side view cross-section of a package with a glass core interposer with an active die complex coupled with the first side of the glass core interposer and a motherboard attached to the second side of the glass core interposer, in accordance with various embodiments. Package 300 includes a glass core interposer 301, which may be similar to substrate 100 of FIG. 1. In embodiments, the glass core interposer 301 may include a glass core 302, a first build up layer 306, and a second build up layer 308, which may be similar to glass core 102, first build up layer 106, and second build up layer 108 of FIG. 1.

A plurality of through vias 304 may extend through the glass core 302, and/or through the first build up layer 306 or the second build up layer 308 as shown. In embodiments, a plurality of dies 320, 321, 322 may be physically and/or electrically coupled with a side of the first build up layer 306 through a set of FLI bumps 324. This physical and/or electrical coupling between the dies 320, 321, 322 through the set of FLI bumps 324 may also be referred to as a direct chip attach technique. In embodiments, the second build up layer 308 may be electrically coupled with one or more of the through vias 304, and also electrically coupled with a MLI 326. The MLI 326 may, in turn, be electrically and/or physically coupled with a motherboard or printed circuit board (PCB) 330.

Embodiments of package 300 may be used in designs for the mobile computing space, where the glass core interposer 301 component and its resulting thermomechanical benefits resulting from using a glass core 302 may enable finer pitch scaling for the bumps 324. In addition, these glass core interposer 301 notations may similarly improve mechanical performance and enable reduced MLI 326 pitches, which may result in a reduced overall glass core interposer 301 form factor in comparison to legacy implementations.

In embodiments, mobile designs may have limits on package 300 thickness (z-height). In embodiments, the use of the glass core 302 within the glass core interposer 301 may be used to improve package warpage characteristics without adding additional core thickness or requiring an additional costly package stiffener. Package 370 shows a top-down view, where dies 320, 321, 322 are physically and/or electrically coupled with the glass interposer 301, which in turn is physically and/or electrically coupled with the motherboard or PCB 330.

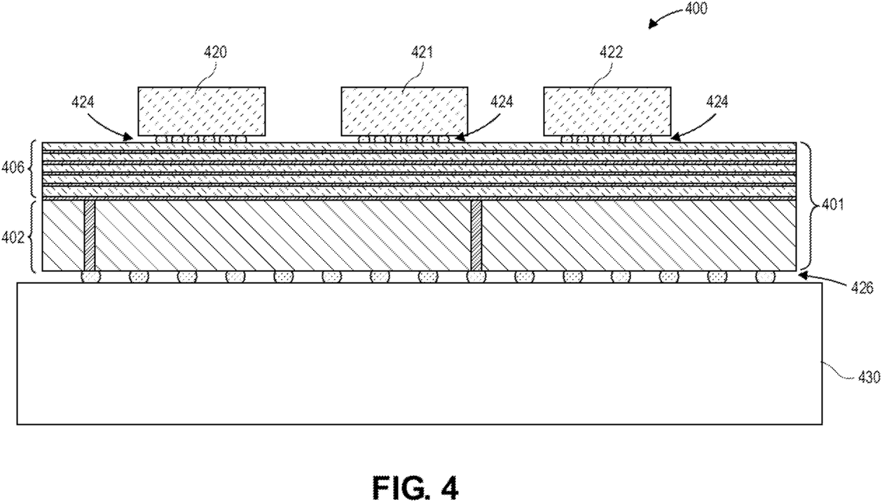

FIG. 4 illustrates a block diagram of a side view cross-section of a package with an active die complex that are electrically coupled using an asymmetric fanout build up layers on glass substrate/interposer which is physically coupled to an organic substrate, in accordance with various embodiments. Package 400 includes a fanout build up layers fabricated on glass interposer 401 that includes a glass core 402 and a front side or top build up layer 406. In embodiments, a plurality of dies 420, 421, 422 may be physically and/or electrically coupled with a side of the first build up layer 406 through a set of bumps 424. In embodiments, these dies 420, 421, 422 may be active dies. In embodiments, the glass interposer 401 may be physically and electrically coupled with a substrate 430 using package side bumps 426.

In embodiments, the dies 420, 421, 422 may be stacked on top of one another (not shown) or maybe stacked on other dies (not shown) that are also coupled with the glass interposer 401. In embodiments, the use of a glass core 402 within package 400 may be implemented in panels, which may remove any reticle limitation for the size of the glass interposer 401. In addition, not only could larger disaggregated die complexes be created, similar to the discussion above, pitch scaling for the dies 420, 421, 422 may also be reduced. This may also be particularly helpful in packages that include bridges, such as an embedded multi-die interconnect (EMIB) bridge, as discussed further below, where a glass layer 402 may decrease warpage and allow for a smaller top die 420, 421, 422 size as compared to legacy implementations.

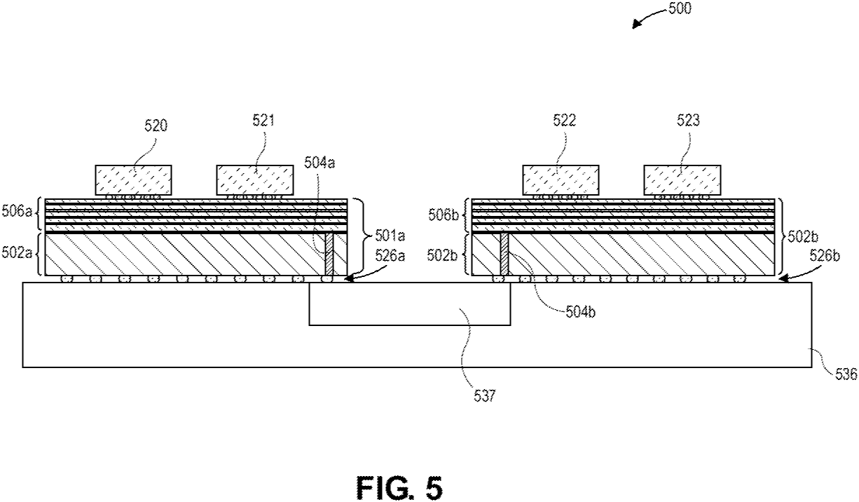

FIG. 5 illustrates a block diagram of a package with two sets of active die complexes each coupled with a silicon interposer that has a glass core, the silicon interposers coupled with a substrate that includes a bridge that is embedded within the substrate, in accordance with various embodiments. Package 500 includes a first interposer 501a and a second interposer 501b, that are electrically coupled using a bridge 537 that is embedded within a substrate 536.

The first interposer 501a may include a core 502a and a first build up layer 506a coupled with the core 502a. In embodiments, the core 502a may be a glass core, and may include one or more TGV 504a that electrically couple the dies 520, 521 with the bridge 537 through MLI 526a. The second interposer 501b may include a core 502b and a first build up layer 506b coupled with the core 502b. In embodiments, the core 502b may be a glass core, and may include one or more TGV 504b that electrically couple the dies 522, 523 with the bridge 537 through MLI 526b.

In embodiments, the substrate 536 may be either a glass substrate or a silicon substrate. In embodiments where the substrate 536 is a glass layer, then the cores 502a, 502b may be organic cores. In embodiments, the bridge 537 may be an EMIB, or may be an open cavity bridge (OCB).

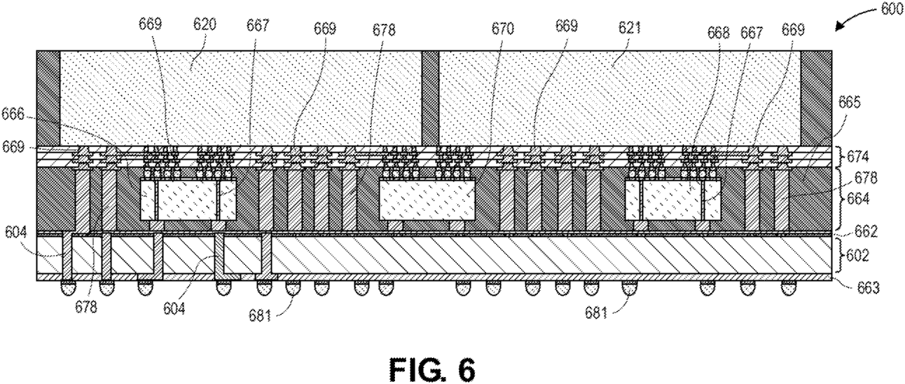

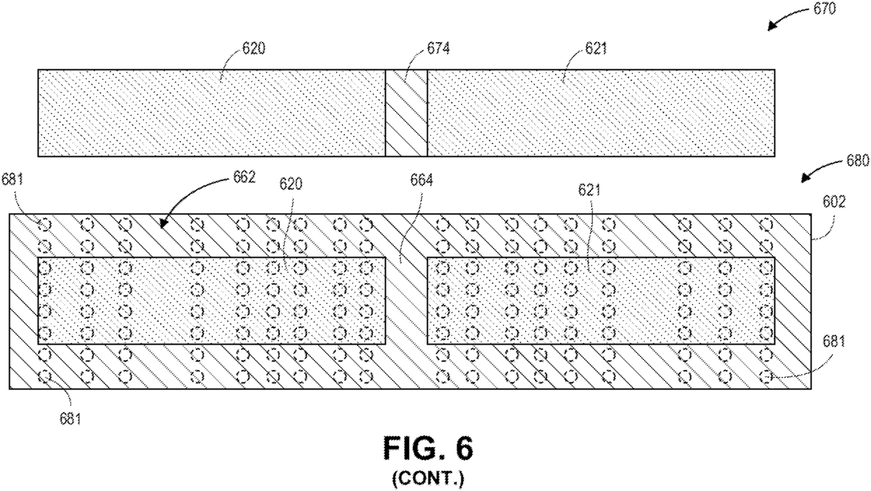

FIG. 6 illustrates a cross-section side view and two top-down views of a stacked die package on a glass substrate, in accordance with various embodiments. Package 600 shows a glass core 602 that may have a first redistribution layer (RDL) 662 on a first side of the glass core 602, and a second redistribution layer 663 on a second side of the glass layer 602 opposite the first side. In embodiments, one or more TGV 604 filled with conductive material such as copper, may electrically couple the first RDL 662 and the second RDL 663.

The first RDL 662 is electrically and physically coupled with a chiplet layer 664. The chiplet layer 664, which may also be referred to as a chiplet base complex, include chiplets 666, 668 with TSVs 667, which may include active circuitry. The chiplet layer 664 may also include chiplets without TSVs 670, which may include bridges or other passive components. The chiplet layer 664 may be coupled to a RDL layer 674 and FLI Bumps that may electrically and/or physically couple with dies 620, 621.

In embodiments, the chiplet layer 664 may include one or more pillars 678 to electrically couple the first RDL layer 662 with the RDL layer 674. The RDL layer 674 includes a plurality of vias 669 to electrically couple the pillars 678 and the chiplets 666, 668, 670 with one or more of the dies 620, 621. In embodiments, a molding 665 may encapsulate one or more components within the chiplet layer 664 to facilitate thermal management and/or package 600 mechanical stability.

A thickness of the glass layer 602 may be chosen based upon the expected mechanical stresses that may be placed on the package 600. In embodiments, a pitch of the TGV 604 within the glass core 602 may be on the order of 50-400 µm, may be filled with copper, and may have a height of 100-750 µm depending upon the thickness of glass core 602. In embodiments, bumps 681 may be physically and/or electrically coupled to the second RDL layer 663 in preparation for electrical and/or physical coupling with a motherboard or with some other substrate (not shown).

Package 670 shows a top-down view of one embodiment of package 600, where the glass core 602 has a similar x-y dimension as the chiplet layer 664, and does not extend beyond a footprint of the dies 620, 621. In these embodiments, the glass core 602, as well as the first RDL 662 or the second RDL 663 are not used as a fan out.

Package 680 shows a top-down view of another embodiment of package 600, where the glass core 602 extends beyond the size of the chiplet layer 664. In these embodiments, the glass layer 602, in addition to the first RDL 662 or the second RDL 663, may be used as a fan out, which may allow bumps 681 to be electrically coupled with the dies 620, 621 and to extend outside the footprint of the chiplet layer 664.

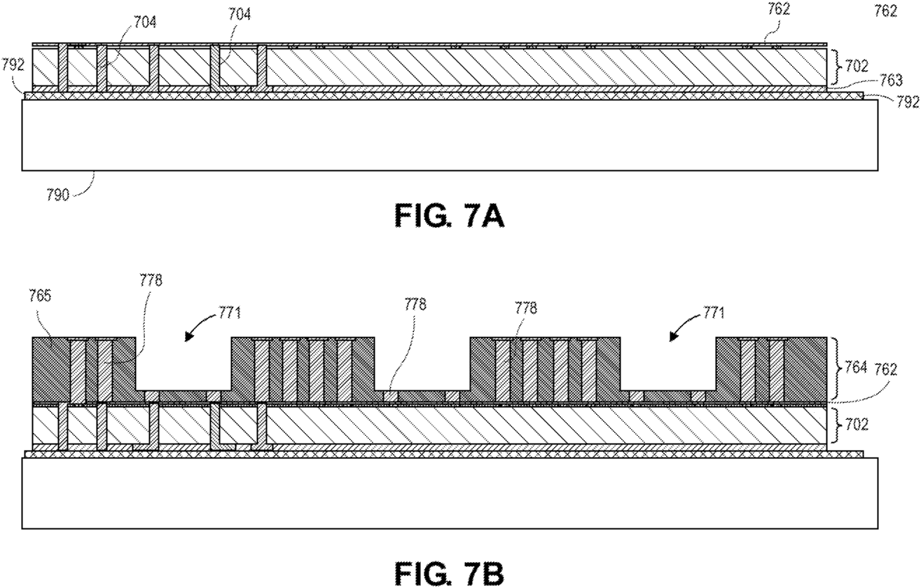

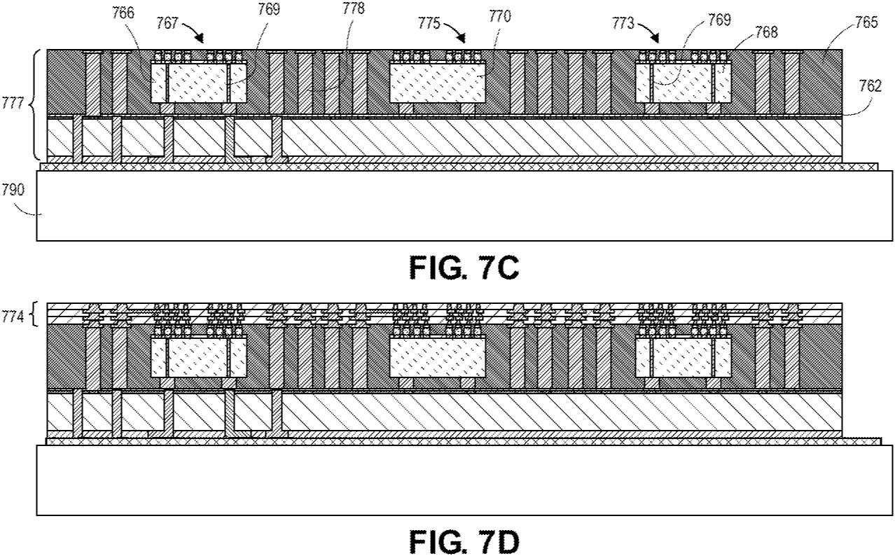

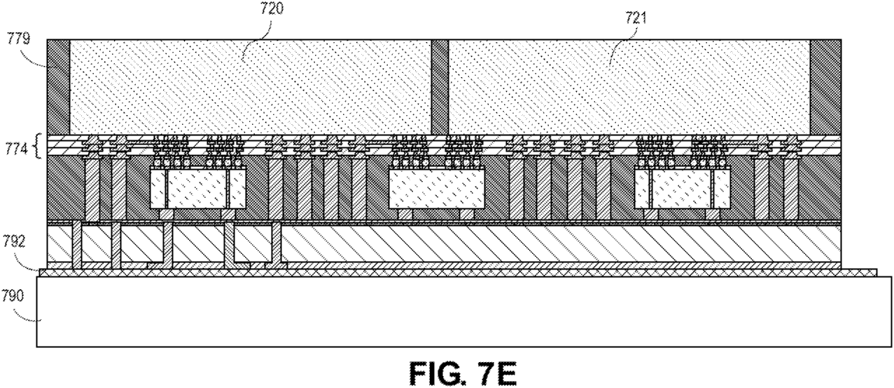

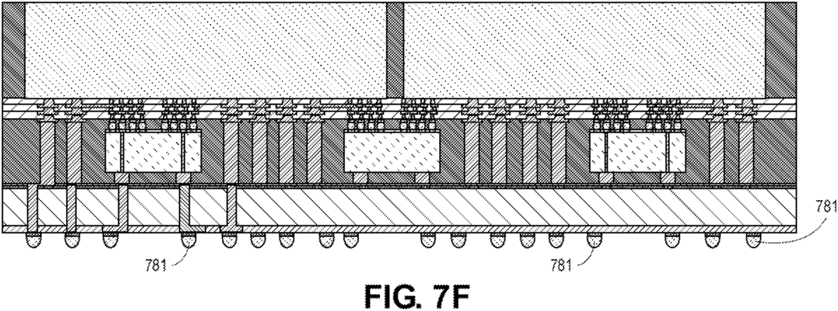

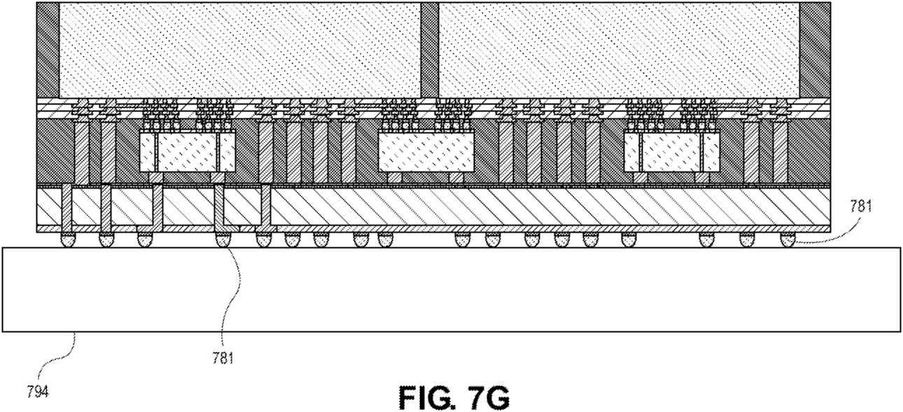

FIGS. 7A-7G illustrates stages in the manufacturing process for creating a stacked die package on a glass substrate, in accordance with various embodiments. FIGS. 7A-7G may be used to manufacture a package similar to package 600 of FIG. 6.

FIG. 7A is a stage in the manufacturing process where a temporary glass carrier 790 is identified on to which a package similar to package 600 of FIG. 6 may be built. In embodiments, this temporary glass carrier 790 may have a coefficient of thermal expansion (CTE) of 3-6 PPM/C, and may have a thickness between 700-800 µm. A release layer 792 may be applied to a surface of the temporary glass carrier 790 to aid in the separation from the package after manufacture. In addition, the temporary glass carrier 790 may include fiducial markers to aid in the manufacturing process.

A glass core 702 is identified, and may be also referred to as a glass interposer wafer. In embodiments, the glass core 702 may have a thickness between 100-500 µm. One or more TGV 704 may be formed within the glass core 702, and may be filled with copper or with some other electrically conductive material. The TGV 704 may have a pitch of 100 µm, and may include metal pads. In embodiments, these metal pads may be electrically coupled with a plurality of TGV 704. The TGV 704 may be used to electrically couple a first RDL layer 762 on a first side of the glass core 702 and a second RDL layer 763 on a second side of the glass core 702. In embodiments, the first RDL layer 762 may be built to support a fan out design as discussed above.

FIG. 7B is a stage in the manufacturing process where a chiplet layer 764 may be built on the first RDL layer 762. In embodiments, pillars 778 may be constructed to electrically couple with the first RDL layer 762. In embodiments, a molding 765 may be applied to encapsulate the pillars 778. In addition, cavities 771 may be formed within the molding 765, into which chiplets may be subsequently placed.

FIG. 7C shows the stage in the manufacturing process where chiplets 766, 768 that include TSVs 769 are placed within cavities 771. In embodiments, chiplets 766, 768 may include but are not limited to voltage regulators (VR), processor, or memory chips. In embodiments, solder interconnects may be used to electrically couple the chiplets 766, 768 with the first RDL 762. In embodiments, chiplets 770 that do not have TSVs, for example bridges, may be placed within cavities 771.

After placement of the chiplets 776, 768, 770, additional copper features and/or bumps 767, 773, 775 may be formed on the chiplets 776, 768, 770. In embodiments, additional mold may be applied, and planarization may be accomplished to expose the copper pillars 778 as well as the additional copper features and/or bumps 767, 773, 775. After this planarization process, the resulting structure 777 may be referred to as a chiplet base complex integrated with a glass interposer.

FIG. 7D shows a stage in the manufacturing process where an RDL layer 774 which may be similar to RDL layer 674 of FIG. 6, is formed. The RDL layer 774 may include multiple RDL layers, and maybe finished bump consisting of a stack with a copper, barrier metal, such as nickel, cobalt iron (CoFe), and the like, in addition to solder. These bumps may be connected to dies 720, 721.

FIG. 7E shows a stage in the manufacturing process where dies 720, 721 are electrically and physically coupled with the RDL layer 774. In embodiments, an additional molding material 779 may be applied and surround the dies 720, 721.

FIG. 7F shows a stage in the manufacturing process where the temporary glass carrier 790 is detached, along with the release layer 792. In embodiments, a laser may be used to facilitate the detachment. In embodiments, one or more bumps 781 may be physically and/or electrically coupled with the second RDL 763.

FIG. 7G shows a stage in the manufacturing process where the one or more bumps 781 are coupled with a substrate 794. In embodiments, the substrate 794 may be a motherboard, or may be some other PCB.

FIG. 8 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 800 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 812 is created by laser pulses from two laser sources 802, 804 on opposite sides of a glass wafer 806. As used herein, a through drill and a through via refers to when the drill or the via starts on one side of the glass/substrate and ends on the other side. A blind drill and a blind via refers to when the drill or the via starts on the surface of the substrate and stops halfway inside the substrate. In embodiments, the laser pulses from the two laser sources 802, 804 are applied perpendicularly to the glass wafer 806 to induce a morphological change 808, which may also be referred to as a structural change, in the glass that encounters the laser pulses. This morphological change 808 includes changes in the molecular structure of the glass to make it easier to etch out (remove a portion of the glass). In embodiments, a wet etch process may be used.

Diagram 820 shows a high level process flow for a double blind shape. A double blind shape 832, 833 may be created by laser pulses from two laser sources 822, 824, which may be similar to laser sources 802, 804, that are on opposite sides of the glass wafer 826, which may be similar to glass wafer 806. In this example, adjustments may be made in the laser pulse energy and/or the laser pulse exposure time from the two laser sources 822, 824. As a result, morphological changes 828, 829 in the glass 826 may result, with these changes making it easier to etch out portions of the glass. In embodiments, a wet etch process may be used.

Diagram 840 shows a high level process flow for a single-blind shape, which may also be referred to as a trench. In this example, a single laser source 842 delivers a laser pulse to the glass wafer 846 to create a morphological change 848 in the glass 846. As described above, these morphological changes make it easier to etch out a portion of the glass 852. In embodiments, a wet etch process may be used.

Diagram 860 shows a high level process flow for a through via shape. In this example, a single laser source 862 applies a laser pulse to the glass 866 to create a morphological change 868 in the glass 866, with the change making it easier to etch out a portion of the glass 872. As shown here, the laser pulse energy and/or laser pulse exposure time from the laser source 862 has been adjusted to create an etched out portion 872 that extends entirely through the glass 866.

With respect to FIG. 8, although embodiments show laser sources 802, 804, 822, 824, 842, 862 as perpendicular to a surface of the glass 806, 826, 846, 866, in embodiments, the laser sources may be positioned at an angle to the surface of the glass, with pulse energy and/or pulse exposure time variations in order to cause a diagonal via or a trench, or to shape the via, such as 812, 872, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 8, through hole vias 812, 872 may be created that are less than 10 µm in diameter, and may have an aspect ratio of 40:1 to 50:1. As a result, a far higher density of vias may be placed within the glass and be placed closer to each other at a fine pitch. In embodiments, this pitch may be 50 µm or less. After creating the vias or trenches, a metallization process may be applied in order to create a conductive pathway through the vias or trenches, for example a plated through hole (PTH). Using these techniques, finer pitch vias may result in better signaling, allowing more I/O signals to be routed through the glass wafer and to other coupled components such as a substrate.

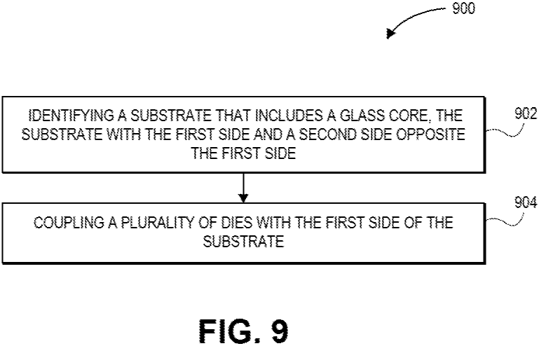

FIG. 9 illustrates an example of a process 900 for coupling a substrate with a glass core with a plurality of dies control warpage in a package, in accordance with various embodiments.

At block 902, the process may include identifying a substrate that includes a glass core, the substrate with the first side and a second side opposite the first side.

At block 904, the process may include coupling a plurality of dies with the first side of the substrate.

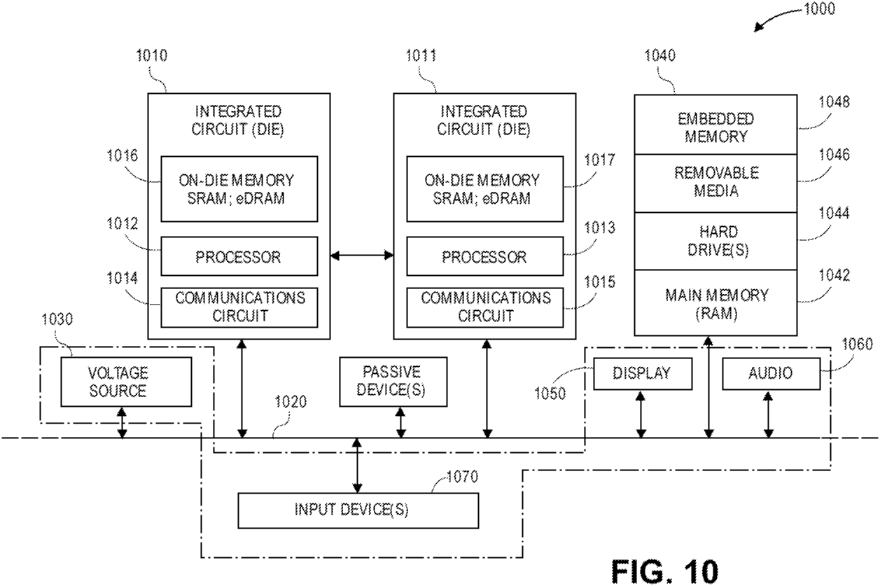

FIG. 10 is a schematic of a computer system 1000, in accordance with an embodiment of the present invention. The computer system 1000 (also referred to as the electronic system 1000) as depicted can embody multiple dies coupled with a glass core substrate, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, multiple dies coupled with a glass core substrate, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 1010 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including a package substrate having multiple dies coupled with a glass core substrate, according to any of the several disclosed embodiments and their equivalents, an electronic system, a computer system, one or more methods of fabricating an integrated circuit, and one or more methods of fabricating an electronic assembly that includes a package substrate having multiple dies coupled with a glass core substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having multiple dies coupled with a glass core substrate embodiments and their equivalents. A foundation substrate may be included, as represented by the dashed line of FIG. 10. Passive devices may also be included, as is also depicted in FIG. 10.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

Example 1 is a package comprising: a substrate that includes a glass core, the substrate with a first side and a second side opposite the first side; and a plurality of dies coupled with the first side of the substrate.

Example 2 includes the package of example 1, wherein at least one of the plurality of dies are stacked on another of the plurality of dies.

Example 3 includes the package example 1, wherein the plurality dies are directly coupled with the first side of the substrate.

Example 4 includes the package of example 3, wherein the plurality of dies are coupled using direct chip attach.

Example 5 includes the package of example 1, wherein the substrate is a first substrate; and further comprising: a second substrate with a first side and a second side opposite the first side, wherein the first side of the second substrate is coupled with the plurality of dies, and wherein the second side of the second substrate is coupled with the first side of the first substrate.

Example 6 includes the package of example 1, further comprising: one or more through glass vias (TGV) extending from the first side of the substrate to the second side of the substrate and through the glass core, the one or more TGV includes electrically conductive material, wherein at least one of the plurality of dies is electrically coupled with at least one of the one or more TGV.

Example 7 includes the package of example 6, wherein the substrate has a thickness of the glass core ranging from 100 µm to 750 µm, and wherein a pitch of the one or more TGV ranging from 50 µm to 30 µm.

Example 8 includes the package of example 6, wherein the substrate is a first substrate; and further comprising: a second substrate with the first side and a second side opposite the first side, wherein the first side of the second substrate is electrically coupled with at least one of the one or more TGV.

Example 9 includes the package of example 8, wherein the second substrate is an organic substrate.

Example 10 includes the package of example 1, further comprising: a bridge within the substrate, a side of the bridge proximate to the first side of the substrate, the bridge electrically coupled with at least two of the plurality of dies.

Example 11 includes the package of example 10, wherein the bridge is a selected one of: an open cavity bridge (OCB) or an Embedded Multi-die Interconnect Bridge (EMIB).

Example 12 includes the package of any one of examples 1-11, wherein the first side of the substrate includes a redistribution layer (RDL), wherein at least one of the plurality of dies is electrically coupled with the RDL.

Example 13 includes a method comprising: identifying a substrate that includes a glass core, the substrate with the first side and a second side opposite the first side; and coupling a plurality of dies with the first side of the substrate.

Example 14 includes the method of example 13, wherein the substrate further includes a redistribution layer (RDL) on the first side of the substrate; and wherein coupling a plurality of dies further includes: directly electrically coupling the plurality of dies with the RDL.

Example 15 includes the method of example 13, wherein the substrate is a first substrate; and further comprising: identifying a second substrate with a first side and a second side opposite the first side; and wherein coupling a plurality of dies with the first side of the first substrate further includes: coupling the first side of the second substrate with the plurality of dies; and coupling the second side of the second substrate with the first side of the first substrate.

Example 16 includes the method of example 13, wherein after the step of identifying a substrate, the method further comprises: creating one or more TGV in the substrate, the TGV including conductive material and extending from a first side of the substrate to a second side of the substrate; and wherein coupling a plurality of dies further includes directly electrically coupling at least one of the dies to at least one of the TGV.

Example 17 includes the method of any one of examples 13-16, wherein after the step of identifying a substrate, the method further comprises: embedding a bridge within at least a portion of the glass core of the substrate, a side of the bridge proximate to the first side of the substrate; and wherein coupling a plurality of dies further includes: electrically coupling one of the plurality of dies with the bridge; and electrically coupling another of the plurality of dies with the bridge.

Example 18 is a system comprising: a package comprising: a first substrate that includes a glass core, the first substrate with a first side and a second side opposite the first side; a plurality of through glass vias (TGV) extending from the first side of the first substrate to the second side of the first substrate and through the glass core, the plurality of TGV includes electrically conductive material; a second substrate with a first side and a second side opposite the first side, the second substrate including a plurality of electrical connections between the first side and the second side, the second side of the second substrate electrically coupled with the first side of the first substrate; at least one of the plurality of dies electrically coupled with the first side of the second substrate; and a third substrate coupled with the package.

Example 19 includes the system of example 18, wherein the third substrate is coupled with the second side of the first substrate, and wherein the substrate is a selected one of: a temporary carrier, an organic substrate, or a motherboard.

Example 20 includes the system of any one of examples 18-19, wherein the second substrate includes a bridge with a side proximate to the first side of the second substrate, and wherein one of the plurality of dies is electrically coupled to another of the plurality of dies the other bridge.

Example 21 includes the system of example 20, wherein the bridge is a selected one of: an EMIB or an OCB.

What is claimed is:

1. A package comprising:
a substrate that includes a glass core, the substrate with a first side and a second side opposite the first side; and
a plurality of dies coupled with the first side of the substrate.

2. The package of claim 1, wherein at least one of the plurality of dies are stacked on another of the plurality of dies.

3. The package claim 1, wherein the plurality dies are directly coupled with the first side of the substrate.

4. The package of claim 3, wherein the plurality of dies are coupled using direct chip attach.

5. The package of claim 1, wherein the substrate is a first substrate; and further comprising:
a second substrate with a first side and a second side opposite the first side, wherein the first side of the second substrate is coupled with the plurality of dies, and wherein the second side of the second substrate is coupled with the first side of the first substrate.

6. The package of claim 1, further comprising:
one or more through glass vias (TGV) extending from the first side of the substrate to the second side of the substrate and through the glass core, the one or more TGV includes electrically conductive material, wherein at least one of the plurality of dies is electrically coupled with at least one of the one or more TGV.

7. The package of claim 6, wherein the substrate has a thickness of the glass core ranging from 100 µm to 750 µm, and wherein a pitch of the one or more TGV ranging from 50 µm to 30 µm.

8. The package of claim 6, wherein the substrate is a first substrate; and further comprising:
a second substrate with the first side and a second side opposite the first side, wherein the first side of the second substrate is electrically coupled with at least one of the one or more TGV.

9. The package of claim 8, wherein the second substrate is an organic substrate.

10. The package of claim 1, further comprising:
a bridge within the substrate, a side of the bridge proximate to the first side of the substrate, the bridge electrically coupled with at least two of the plurality of dies.

11. The package of claim 10, wherein the bridge is a selected one of: an open cavity bridge (OCB) or an Embedded Multi-die Interconnect Bridge (EMIB).

12. The package of claim 1, wherein the first side of the substrate includes a redistribution layer (RDL), wherein at least one of the plurality of dies is electrically coupled with the RDL.

13. A method comprising:
identifying a substrate that includes a glass core, the substrate with the first side and a second side opposite the first side; and
coupling a plurality of dies with the first side of the substrate.

14. The method of claim 13, wherein the substrate further includes a redistribution layer (RDL) on the first side of the substrate; and
wherein coupling a plurality of dies further includes: directly electrically coupling the plurality of dies with the RDL.

15. The method of claim 13, wherein the substrate is a first substrate; and further comprising:
identifying a second substrate with a first side and a second side opposite the first side; and
wherein coupling a plurality of dies with the first side of the first substrate further includes:
coupling the first side of the second substrate with the plurality of dies; and
coupling the second side of the second substrate with the first side of the first substrate.

16. The method of claim 13, wherein after the step of identifying a substrate, the method further comprises:
creating one or more TGV in the substrate, the TGV including conductive material and extending from a first side of the substrate to a second side of the substrate; and
wherein coupling a plurality of dies further includes directly electrically coupling at least one of the dies to at least one of the TGV.

17. The method of claim 13, wherein after the step of identifying a substrate, the method further comprises:
embedding a bridge within at least a portion of the glass core of the substrate, a side of the bridge proximate to the first side of the substrate; and
wherein coupling a plurality of dies further includes:
electrically coupling one of the plurality of dies with the bridge; and
electrically coupling another of the plurality of dies with the bridge.

18. A system comprising:
a package comprising:
a first substrate that includes a glass core, the first substrate with a first side and a second side opposite the first side;
a plurality of through glass vias (TGV) extending from the first side of the first substrate to the second side of the first substrate and through the glass core, the plurality of TGV including electrically conductive material;
a second substrate with a first side and a second side opposite the first side, the second substrate including a plurality of electrical connections between the first side and the second side, the second side of the second substrate electrically coupled with the first side of the first substrate;
at least one of the plurality of dies electrically coupled with the first side of the second substrate; and
a third substrate coupled with the package.

19. The system of claim 18, wherein the third substrate is coupled with the second side of the first substrate, and wherein the substrate is a selected one of: a temporary carrier, an organic substrate, or a motherboard.

20. The system of claim 18, wherein the second substrate includes a bridge with a side proximate to the first side of the second substrate, and wherein one of the plurality of dies is electrically coupled to another of the plurality of dies the other bridge.

21. The system of claim 20, wherein the bridge is a selected one of: an EMIB or an OCB.
